(19) United States
(12) Patent Application Publication
(10) Pub. No.: US 2026/0130145 A1
(43) Pub. Date: May 7, 2026

(54) ETCHING SYSTEM FOR FORMING RECESSED FEATURES WITH HIGH ASPECT RATIO

(71) Applicant: Tokyo Electron Limited, Tokyo (JP)

(72) Inventor: Christopher CATANO, Albany, NY (US)

(73) Assignee: Tokyo Electron Limited, Tokyo (JP)

(21) Appl. No.: 18/940,742

(22) Filed: Nov. 7, 2024

(51) Int. Cl. H01L 21/311; H01L 21/3065; H01L 21/308; H01L 21/67

(52) U.S. Cl. CPC H10P 50/283; H10P 50/242; H10P 50/691; H10P 50/73; H10P 72/0421

(57) ABSTRACT

A method includes providing a structure in a chamber, wherein the structure comprising a first layer disposed over a substrate and a second layer disposed over the first layer; forming a mask over the structure, wherein the mask includes a plurality of protruding structures defining a plurality of openings, respectively; etching, through the mask, one or more portions of the second layer using a first gas to expose one or more portions of the first layer; based on a second gas, forming a plurality of cap structures covering upper portions of the protruding structures, respectively, and etching, through the mask with the cap structures, the one or more exposed portions of the first layer; and etching, through the mask, one or more portions of another second layer disposed below the first layer using the first gas.

### FIELD OF THE DISCLOSURE

This disclosure relates to semiconductor processing technology, and more particularly, to method and apparatus for forming a recessed feature with a high aspect ratio.

### BACKGROUND

One process frequently employed during fabrication of semiconductor devices is the formation of an etched cylinder or other recessed feature in a stack of dielectric-containing material. For instance, such processes are commonly used in memory applications such as fabricating 3D NAND (also referred to as vertical NAND or V-NAND) structures. As the semiconductor industry advances and device dimensions become smaller, such features are increasingly difficult to etch in a uniform manner, especially for high aspect ratio cylinders having narrow widths and/or deep depths.

### SUMMARY

At least one aspect of the present disclosure is directed to a method for manufacturing semiconductor devices. The method includes (a) providing a structure in a chamber, wherein the structure comprising a plurality of first layers and a plurality of second layers alternately stacked on top of one another; (b) exposing the structure to a first gas, thereby removing, through a mask including a plurality of protruding structures, one or more portions of a topmost one of the plurality of second layers that was intact; (c) exposing the structure to a second gas, thereby forming a cap structure around an upper portion of each of the plurality of protruding structures and removing, through the mask with the cap structure, one or more portions of a topmost one of the plurality of first layers that was intact; and (d) exposing the structure to the first gas, thereby removing one or more portions of a next topmost one of the first layers that was intact.

In some embodiments, the method includes repeating the step (c) and the step (d) until one or more portions of a bottommost one of the plurality of first layers are removed through the mask.

In some embodiments, the first layers each include polysilicon, and the second layers each include silicon oxide.

In some embodiments, the first layers each include silicon nitride, and the second layers each include silicon oxide.

In some embodiments, the cap structure overlays a top surface of each of the protruding structures and extending along upper portions of sidewalls of each of the protruding structures.

In some embodiments, the steps (b) to (d) are performed in the chamber.

In some embodiments, the first gas includes fluoro-carbons, hydro-fluoro-carbons, or combinations thereof, and the second gas includes SiCl₄. The cap structure includes SiOClₓ.

In some embodiments, the first gas is configured to remove the cap structure.

In some embodiments, the method includes forming the mask over the structure.

The mask exposes the one or more portions of the topmost second layer, with the topmost first layer disposed right therebelow.

Another aspect of the present disclosure is directed to a method for manufacturing semiconductor devices. The method includes providing a structure in a chamber, wherein the structure comprising a first layer disposed over a substrate and a second layer disposed over the first layer; forming a mask over the structure, wherein the mask includes a plurality of protruding structures defining a plurality of openings, respectively; etching, through the mask, one or more portions of the second layer using a first gas to expose one or more portions of the first layer; based on a second gas, forming a plurality of cap structures covering upper portions of the protruding structures, respectively, and etching, through the mask with the cap structures, the one or more exposed portions of the first layer; and etching, through the mask, one or more portions of another second layer disposed below the first layer using the first gas.

In some embodiments, the first layer includes polysilicon, and the second layer includes silicon oxide.

In some embodiments, the first layer includes silicon nitride, and the second layer includes silicon oxide.

In some embodiments, the first gas includes fluoro-carbons, hydro-fluoro-carbons, or combinations thereof, and the second gas includes SiCl₄. The cap structures each include SiOClₓ.

In some embodiments, the first gas is configured to remove the cap structures.

In some embodiments, the method includes forming the mask over the structure.

The mask exposes the one or more portions of the second layer, with the first layer disposed right therebelow.

Yet another aspect of the present disclosure is directed to an etching system. The etching system includes a chamber; a wafer holder configured to place a structure in the chamber, wherein the structure includes a first layer and a second layer disposed above the first layer; a first gas source configured to provide a first gas onto the structure, such that one or more portions of the second layer of the structure are etched through a plurality of openings to expose corresponding portions of the first layer of the structure; and a second gas source configured to provide a second gas onto the structure, such that the one or more exposed portions of the first layer are etched through the plurality of openings being narrowed.

In some embodiments, the first layer includes polysilicon, and the second layer includes silicon oxide.

In some embodiments, the first layer includes silicon nitride, and the second layer includes silicon oxide.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of an example method for forming a recessed feature extending through a stack, according to various embodiments.

FIGS. 2A, 2B, 2C, 2D, and 2E illustrate cross-sectional views of a semiconductor device at various fabrication stages, respectively, according to various embodiments.

FIG. 3 illustrates a schematic diagram of a plasma-assisted etching system, according to various embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presented.

Reference will now be made to the figures, which for the convenience of visualizing the fabrication techniques described herein, illustrate a variety of materials undergoing a process flow in various views. Unless expressly indicated otherwise, each Figure represents one (or a set) of fabrication steps in a process flow for manufacturing the devices described herein. In the various views of the Figures, connections between conductive layers or materials may or may not be shown. However, it should be understood that connections between various layers, masks, or materials may be implemented in any configuration to create electric or electronic circuits. When such connections are shown, it should be understood that such connections are merely illustrative and are intended to show a capability for providing such connections, and should not be considered limiting to the scope of the claims.

Likewise, although the Figures and aspects of the disclosure may show or describe devices herein as having a particular shape, it should be understood that such shapes are merely illustrative and should not be considered limiting to the scope of the techniques described herein. For example, the techniques described herein may be implemented in any shape or geometry for any material or layer to achieve desired results. In addition, examples in which two transistors or devices are shown stacked on top of one another are shown for illustrative purposes only, and for the purposes of simplicity. Indeed, the techniques described herein may provide for one to any number of stacked devices. Further, although the devices fabricated using these techniques are shown as transistors, it should be understood that any type of electric electronic device may be manufactured using such techniques, including but not limited to transistors, variable resistors, resistors, and capacitors.

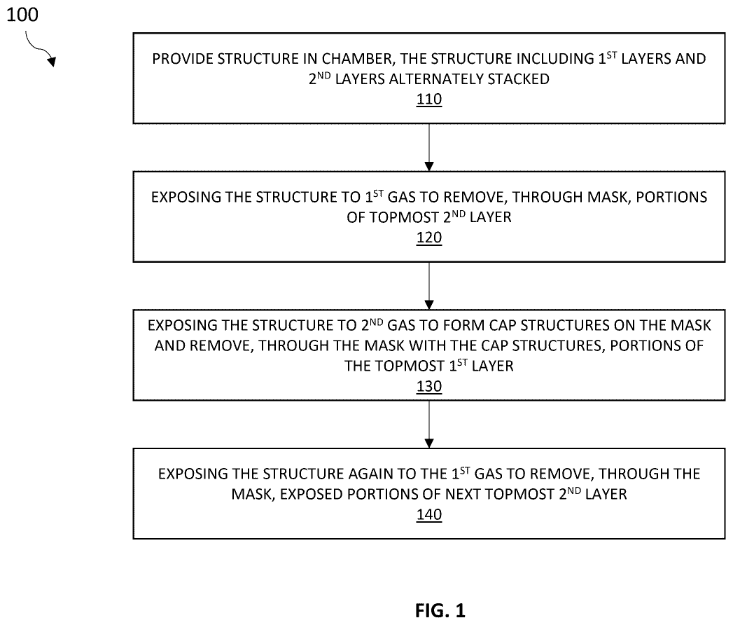

FIG. 1 illustrates a flow chart of an example method 100 for (e.g., partially) fabricating a complete semiconductor device, in accordance with various embodiments. For example, operation of the method 100 may be performed to form a number of recessed features of a three-dimensional (3D) memory device, in which each of the recessed features can have a relatively high aspect ratio. In some embodiments, the recessed feature can be formed by etching a structure (e.g., a stack) that includes at least two different layers alternately stacked on top of one another. One or more operations of the method 100 may be omitted, added, modified, or combined. The operations of the method 100 may be performed sequentially or concurrently. The operations of the method 100 can be performed in other order or sequence, not limited to those described herein.

The method 100 may start with operation 110 of providing a structure in a chamber, in accordance with various embodiments. The structure may include a stack of alternately arranged first layers and second layers. For example, a bottommost one of the first layers may be disposed over a substrate, with by a bottommost one of the second layers disposed on top of the bottommost first layer, with by a next, bottommost one of the first layers disposed on top of the bottommost second layer, and so on. In one aspect, the first layer includes polysilicon, and the second layer includes silicon oxide. In another aspect, the first layer includes silicon nitride, and the second layer includes silicon oxide.

The method 100 may proceed to operation 120 of exposing the structure to a first gas so as to remove, through a mask, a number of portions of the topmost second layer, in accordance with various embodiments. For example, when providing the structure in the chamber, a mask, which has a pattern (e.g., holes or openings) configured to expose a number of portions of the topmost second layer, may have been formed over the structure. Stated another way, the mask can have a number of protruding structures extending away from the structure. Each of the holes of the mask can be defined or otherwise formed by the neighboring ones of the protruding structures. As such, prior to applying the first gas into the chamber, the topmost second layer (and the underlying layers) may still remain intact. In some embodiments, the first gas can include an etching gas that can etch silicon oxide. With plasma activated in the chamber, the first gas can follow the pattern of the mask to perform an anisotropic (or dry) etching process on the topmost second layer. To sustain the plasma (or draw ions from the plasma), a bias power or low-frequency (e.g., in the range of 100 kHz to 13 MHz) power may be applied to a bottom electrode of the chamber, in which the bottom electrode is disposed beneath the structure and the plasma is formed above the structure. In some embodiments, such a bias power can be in the order from about 10 W to about 10 kW.

As a non-limiting example, the first gas include an oxide-etching gas. For instance, the first gas may include fluoro-carbons and/or hydro-fluoro-carbons, e.g., C₄F₈, C₄F₆, CsF₈, CF₄, CH₃F, CF₃H, CH₂F₂, COS, CS₂, CF₃I, C₂F₃I, C₂F₅I, CFN, or combinations thereof. Other than the first gas, O₂ and Ar may be added. Other diluent in addition to Ar, for example, He, Kr, and Xe may be added. For example, after the structure is loaded into the chamber and secured, the first gas (together with one or more other gases) may be applied into the chamber to etch the topmost second layer through the mask. As such, the pattern on the mask can be transferred to the topmost second layer. Further, the next lower layer, e.g., the topmost first layer, can have a number of portions exposed through the transferred pattern in the topmost second layer.

The method 100 may proceed to operation 130 of exposing the structure to a second gas so as to form a number of cap structures on the mask and remove, through the mask with the cap structures, a number of portions of the topmost first layer, in accordance with various embodiments. For example, after the portions of the topmost first layer are exposed (e.g., by the transferred pattern in the topmost second layer), the second gas can be applied into the same chamber to form a cap structure around an upper portion of each of the protruding structures of the mask. In some embodiments, the second gas can include SiCl₄, O₂, Cl₂, one or more inert gases, or combinations thereof. In some embodiments, the mask may be or include an amorphous carbon layer (ACL) or an organic under layer (ODL) such as, for example, CH₄ and/or C₂H₂, and thus, with the second gas including SiCl₄, the cap structure can be formed of SiOClₓ.

The cap structure can be formed over a top surface of the protruding structure and along upper portions of sidewalls of the protruding structure, which can advantageously improve mask selectivity and increase an aspect ratio of the feature to be formed in the stack. For example, with the cap structure overlaying the upper portion of each of the protruding structures of the mask, the second gas can be more directed to etch the exposed topmost first layer. Further, with the cap structure laterally covering a portion of each of the openings of the mask, a smaller feature (e.g., a number of narrower openings) can be formed in the topmost first layer. Upon those openings be formed in the topmost first layer, a number of portions of the next lower layer (the next topmost second layer) can be exposed.

The method 100 may proceed to operation 140 of exposing the structure again to the first gas so as to remove a number of portions of the next topmost second layer through the mask, in accordance with various embodiments. For example, after exposing the next topmost second layer, the first gas is again applied into the chamber to remove those exposed portions of the next topmost second layer. In some embodiments, the first gas can remove the cap structures, while etching the second layer. With multiple pairs of the first and second layers, the operation 130 and operation 140 may be iteratively performed until reaching a desired depth of the recessed structure. For example, with the stack having 10 pairs of the first and second layers, at least 10 iterations of the operation 130 and operation 140 may be performed. Stated another way, the operation 130 and operation 140 may be iteratively performed until the pattern is transferred to the bottommost first layer.

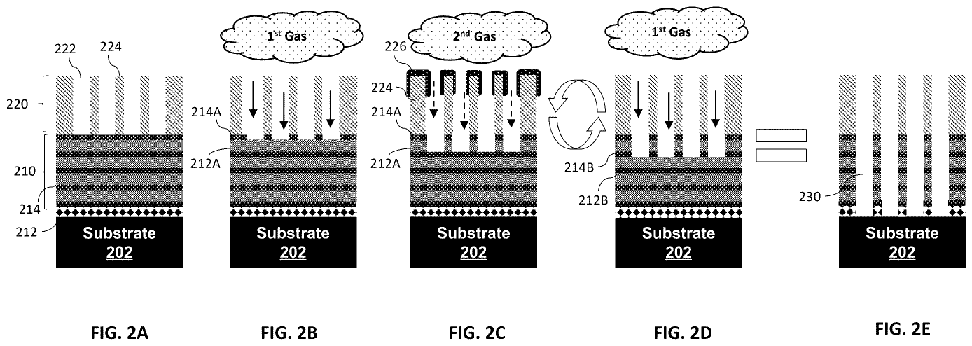

FIG. 2A to FIG. 2E illustrate cross-sectional views of a structure manufactured via some of the operations of the method 100, respectively. Accordingly, the following discussion of FIGS. 2A-2E may sometimes be referred again to the operation of FIG. 1. In some embodiments, the structure is a recessed structure (sometimes referred to as an aperture or via) with a high aspect ratio. Further, such a recessed structure penetrates through a plural number of first layers and a plural number of second layers alternately stacked on top of one another, which can be subsequently formed as a portion of a three-dimensional (3D) NAND memory device. However, it should be understood that the techniques, disclosed herein, are not limited to forming a recessed structure for a memory device.

In FIG. 2A, which may correspond to the operation 110 of FIG. 1, a structure including a stack 210 formed over a substrate 202 is provided. The stack 210 includes a number of first layers 212 and a number of second layers 214. The first layers 212 and the second layers 214 are alternately arranged on top of one another. For example, a bottommost one of the first layers 212 is formed over the substrate 202, with a bottommost one of the second layers 214 formed on top of the bottommost first layer 212, with a next, bottommost one of the first layers 212 formed on top of the bottommost second layer 214, and so on. The substrate 202 may be a silicon or semiconductor wafer. In one aspect, the first layer 212 includes polysilicon, and the second layer 214 includes silicon oxide. In another aspect, the first layer 212 includes silicon nitride, and the second layer 214 includes silicon oxide. Over the stack 210, a mask 220, including a pattern 222, can be formed. Despite being shown as a single layer, the mask 220 can include a plural number of layers.

In FIG. 2B, which may correspond to the operation 120 of FIG. 1, a first gas is applied onto the structure. The first gas may include fluorocarbons and/or hydrofluorocarbons, that is configured to etch the material of the second layer 214. With the mask 220 disposed over a topmost one of the second layers, 214A, a number of portions of the topmost second layer 214A are exposed. For example, the mask 220 includes a plurality of openings 222 defined by a plurality of protruding structures 224, respectively. The first gas can follow the openings 222 or the protruding structures 224 of the mask 220 to directionally (e.g., vertically) etch the exposed portions of the topmost second layer 214A. After etching (or removing) the portions of the topmost second layer 214A, a number of portions of a topmost one of the first layers, 212A, are exposed.

In FIG. 2C, which may correspond to the operation 130 of FIG. 1, a second gas is applied onto the structure. The second gas may include SiCl₄, O₂, Cl₂, one or more inert gases, or combinations thereof, that is configured to form a cap structure 226 around an upper portion of each of the protruding structures 224. As shown in the non-limiting example of FIG. 2C, the cap structure 226 can be formed to overlay a top surface of each of the protruding structures 224, and further extend along upper portions of sidewalls of each of the protruding structures 224. Equivalently, the openings 222 of the mask 220 may become narrower. In FIG. 2D, which may correspond to the operation 140 of FIG. 1, the first gas is again applied onto the structure to remove exposed portions of the next topmost second layer 214B, thereby portions of the next topmost first layer 212B. Depending on the number of pairs of the first layer 212 and second layer 214, a corresponding number of iterations of FIG. 2C and FIG. 2D may be performed, which can result in transferring the pattern 222 of the mask 220 to the stack 210 as recessed features 230, as shown in FIG. 2E.

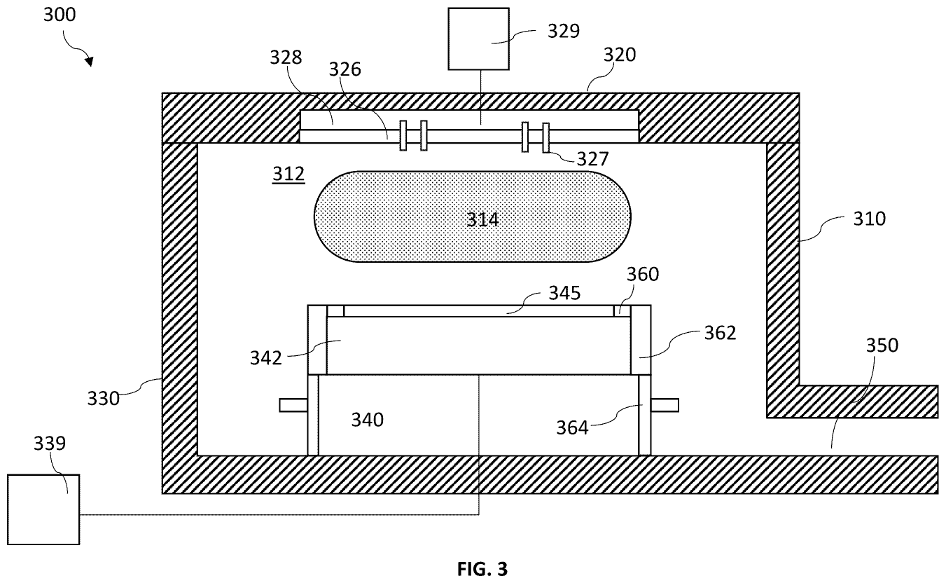

FIG. 3 illustrates an etching system 300, in accordance with various embodiments of the present disclosure. The etching system 300 is configured to perform a plasma-assisted etching process on a substrate. For example, the etching system 300 can etch a semiconductor device using plasma generated. However, it should be understood that the etching system 300 is not limited to performing an etching process, and can perform other suitable semiconductor-related process while remaining within the scope of the present disclosure.

As shown, the etching system 300 includes a chamber 310, an upper assembly 320, a side assembly 330, a substrate holder 340 for supporting a substrate 345, and a pumping duct 350 coupled to a vacuum pump (not shown) for providing a reduced pressure atmosphere in the chamber 310. The chamber 310 can facilitate the formation of plasma 314 in a process space 312 adjacent the substrate 345. For example, the plasma 314 may be generated above the substrate 345. The generated plasma 314 can be utilized to create materials specific to a pre-determined materials process, and/or to aid the removal of material from the exposed surfaces of substrate 345. The etching system 300 may be configured to process substrates of any size, such as 200 mm substrates, 300 mm substrates, 450 mm substrates, or larger. For example, the etching system 300 may comprise a plasma etching system.

In the illustrative embodiment of FIG. 3, the upper assembly 320 may include an upper electrode vertically opposite to the top surface of the substrate 345. For example, the upper assembly 320 can include an upper electrode plate 326 and an upper electrode 328. In some embodiments, the upper electrode 328 may be electrically coupled to a first or upper power supply 329, and the upper electrode plate 326 may be composed of a material compatible with plasma in the process space 312. The first power supply 329 can generate or otherwise output a first signal (e.g., power) with a high frequency suitable for plasma generation. The first signal may sometimes be referred to as a source power for generating plasma, e.g., 314. The source power can be applied to the upper electrode 328. Although not shown, the first power supply 329 can be operatively coupled to the upper electrode 328 though a matching device and a power supply rod, which constitute a part of a high-frequency transmission path for sending the high-frequency source power to the upper electrode 328. The first power supply 329 may further include a system configured to perform at least one of monitoring, adjusting, or controlling the polarity, current, voltage, or on/off state of the first signal (e.g., the source power).

Although not shown, it should be understood that the upper assembly 320 can include a gas buffer room formed therein. The upper assembly 320 can further include, in its bottom surface, a multiple number of gas holes 327 extended from the gas buffer room, and the gas holes 327 communicate with gas discharge holes formed along the upper electrode plate 326, respectively. The gas buffer room can be connected to a plural number of processing gas supply sources via a plural number of gas supply lines, respectively. For example, a first one of the processing gas supply source can provide the first gas discussed above, and a second one of the processing gas supply source can provide the second gas discussed above. The processing gas supply source is provided with a mass flow controller (MFC) and an opening/closing valve. If a certain processing gas (etching gas) is introduced into the gas buffer room from the processing gas supply source, the processing gas is then discharged in a shower shape from the gas discharge holes of the upper electrode plate 326 into the process space 312 toward the substrate 345. In such a configuration, the upper electrode 328 and/or the upper electrode plate 326 can sometimes serve as a part of the shower head that supplies the processing gas into the process space 312.

The substrate holder 340 can include a focus ring 360, a shield ring 362, and a bellows shield 364. The focus ring 360 may be interposed between the substrate 345 and the shield ring 362. The focus ring 360 may be removably fastened to the substrate holder 340. The substrate 345 can be affixed to the substrate holder 340 via a clamping system (not shown), such as a mechanical clamping system or an electrical clamping system (e.g., an electrostatic clamping system). Furthermore, the substrate holder 340 can include a heating system (not shown) or a cooling system (not shown) that is configured to adjust and/or control a temperature of the substrate holder 340 and the substrate 345. The heating system or cooling system may comprise a re-circulating flow of heat transfer fluid that receives heat from the substrate holder 340 and transfers heat to a heat exchanger system (not shown) when cooling, or transfers heat from the heat exchanger system to the substrate holder 340 when heating. Alternatively or additionally, heating/cooling elements, such as resistive heating elements, or thermo-electric heaters/coolers can be included in the substrate holder 340, as well as the chamber wall of the chamber 310 and any other component within the etching system 300.

The substrate holder 340 can further include a substrate holder or lower electrode 342 operatively coupled to a second or lower power supply 339. The second power supply 339 can generate or otherwise output a second signal (e.g., power) with a low frequency (compared to the frequency generated by the first power supply 329) suitable for drawing ions in the process space 312. The second signal may sometimes be referred to as a bias power for drawing ions generated during the generation of plasma 314. The bias power, which is provided with an oscillating negative voltage, can be applied to the lower electrode 342. Although not shown, the second power supply 339 can be operatively coupled to the lower electrode 342 though a matching device and a power supply rod, which constitute a part of a low-frequency transmission path for sending the low-frequency source power to the lower electrode 342. The second power supply 339 may further include a system configured to perform at least one of monitoring, adjusting, or controlling the polarity, current, voltage, or on/off state of the second signal (e.g., the bias power).

In some embodiments, each of these upper and lower electrodes may sometimes be referred to as a chamber component. Further, a pair of the chamber components are arranged along opposite edges of the process space 312, respectively. For example, the upper electrode 328 and the lower electrode 342 may be arranged along an upper edge and a lower edge of the process space 312, respectively. In some embodiments, the upper electrode 328 and the lower electrode 342 can each be formed as a multi-piece structure or a single-piece structure. In the example where the electrode 328/342 is formed as a multi-piece structure, different pieces can be electrically coupled to respective power signals.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for manufacturing semiconductor devices, comprising:
(a) providing a structure in a chamber, wherein the structure comprising a plurality of first layers and a plurality of second layers alternately stacked on top of one another;
(b) exposing the structure to a first gas, thereby removing, through a mask including a plurality of protruding structures, one or more portions of a topmost one of the plurality of second layers that was intact;
(c) exposing the structure to a second gas, thereby forming a cap structure around an upper portion of each of the plurality of protruding structures and removing, through the mask with the cap structure, one or more portions of a topmost one of the plurality of first layers that was intact; and
(d) exposing the structure to the first gas, thereby removing one or more portions of a next topmost one of the first layers that was intact.

2. The method of claim 1, further comprising repeating the step (c) and the step (d) until one or more portions of a bottommost one of the plurality of first layers are removed through the mask.

3. The method of claim 1, wherein the first layers each include polysilicon, and the second layers each include silicon oxide.

4. The method of claim 1, wherein the first layers each include silicon nitride, and the second layers each include silicon oxide.

5. The method of claim 1, wherein the cap structure overlays a top surface of each of the protruding structures and extending along upper portions of sidewalls of each of the protruding structures.

6. The method of claim 1, wherein the steps (b) to (d) are performed in the chamber.

7. The method of claim 1, wherein the first gas includes fluoro-carbons, hydro-fluoro-carbons, or combinations thereof, and the second gas includes SiCl₄.

8. The method of claim 7, wherein the cap structure includes SiOClₓ.

9. The method of claim 1, wherein the first gas is configured to remove the cap structure.

10. The method of claim 1, further comprising:
forming the mask over the structure;
wherein the mask exposes the one or more portions of the topmost second layer, with the topmost first layer disposed right therebelow.

11. A method for manufacturing semiconductor devices, comprising:
providing a structure in a chamber, wherein the structure comprising a first layer disposed over a substrate and a second layer disposed over the first layer;
forming a mask over the structure, wherein the mask includes a plurality of protruding structures defining a plurality of openings, respectively;
etching, through the mask, one or more portions of the second layer using a first gas to expose one or more portions of the first layer;
based on a second gas, forming a plurality of cap structures covering upper portions of the protruding structures, respectively, and etching, through the mask with the cap structures, the one or more exposed portions of the first layer; and
etching, through the mask, one or more portions of another second layer disposed below the first layer using the first gas.

12. The method of claim 11, wherein the first layer includes polysilicon, and the second layer includes silicon oxide.

13. The method of claim 11, wherein the first layer includes silicon nitride, and the second layer includes silicon oxide.

14. The method of claim 11, wherein the first gas includes fluoro-carbons, hydro-fluoro-carbons, or combinations thereof, and the second gas includes SiCl₄.

15. The method of claim 14, wherein the cap structures each include SiOClₓ.

16. The method of claim 11, wherein the first gas is configured to remove the cap structures.

17. The method of claim 11, further comprising:
forming the mask over the structure;
wherein the mask exposes the one or more portions of the second layer, with the first layer disposed right therebelow.

18. An etching system, comprising:
a chamber;
a wafer holder configured to place a structure in the chamber, wherein the structure includes a first layer and a second layer disposed above the first layer;
a first gas source configured to provide a first gas onto the structure, such that one or more portions of the second layer of the structure are etched through a plurality of openings to expose corresponding portions of the first layer of the structure; and
a second gas source configured to provide a second gas onto the structure, such that the one or more exposed portions of the first layer are etched through the plurality of openings being narrowed.

19. The etching system of claim 18, wherein the first layer includes polysilicon, and the second layer includes silicon oxide.

20. The etching system of claim 18, wherein the first layer includes silicon nitride, and the second layer includes silicon oxide.
